(19) United States
(12) Patent Application Publication
(10) Pub. No.: US 2025/0216444 A1
(43) Pub. Date: Jul. 3, 2025

(54) ANTI-CONDENSATION LOW-TEMPERATURE TESTING MODULE AND CHIP TESTING APPARATUS HAVING THE SAME

(71) Applicant: CHROMA ATE INC., Taoyuan City (TW)

(72) Inventors: Yu-Wei Chuang, Taoyuan City (TW); Xin-Yi Wu, Taoyuan City (TW); Jui-Che Chou, Taoyuan City (TW)

(73) Assignee: CHROMA ATE INC., Taoyuan City (TW)

(21) Appl. No.: 18/882,149

(22) Filed: Sep. 11, 2024

(30) Foreign Application Priority Data
Dec. 29, 2023 (TW) 112151738

(51) Int. Cl. G01R 31/28

(52) U.S. Cl. CPC G01R 31/2877

(57) ABSTRACT

An anti-condensation low-temperature testing module and a chip testing apparatus having the same are provided. The low-temperature testing module includes a low-temperature dry-gas supplying device, a low-temperature chamber, a low-temperature generating device, and a communicating pipe. The low-temperature dry-gas supplying device is configured to provide a low-temperature dry-gas to a chip socket of a testing base. The low-temperature generating device is arranged in the low-temperature chamber and coupled to the testing base. The low-temperature generating device is configured to cool down the testing base. One of two ends of the communicating pipe is in communication with the chip socket of the testing base, and the other end of the communicating pipe is in communication with the low-temperature chamber.

### CROSS-REFERENCE TO RELATED APPLICATION

This non-provisional application claims priority under 35 U.S.C. § 119 (a) to Patent Application No. 112151738 filed in Taiwan, R.O.C. on Dec. 29, 2023, the entire contents of which are hereby incorporated by reference.

### BACKGROUND

### Technical Field

The present disclosure relates to chip low-temperature testing technologies, and particularly relates to an anti-condensation low-temperature testing module and a chip testing apparatus having the same.

### Related Art

Package on package (POP) is a packaging technology for integrated circuits, in which the POP technology is configured to combine a plurality of elements into a packaged chip in a vertically stacking manner. Generally, in the configurations of a POP chip, a memory module or a communication module is stacked on top of a processing module. However, the configurations make the POP chip unable to have upper surface conduction to perform temperature-control when the POP chip is tested under a low-temperature (such as but not limited to −40 degrees Celsius to −20 degrees Celsius). The reasons for this situation are: first, because the thermal resistance between the packages is large, the temperature-control method using upper surface conduction may cause the memory module or the communication module to be overcooled or may cause the processing module to be overheated; second, because the communication module has a radio-frequency circuit, a metal shield (for example, a metal heat sink for upper surface conduction) cannot be arranged on the POP chip having the communication module to prevent the radio-frequency circuit from being interfered which will cause the failure of the radio-frequency circuit. Therefore, chip low-temperature testing technologies for the POP chip known to the inventor merely adopt a testing base under the chip to cool down the chip.

On the other hand, because the entire testing apparatus and the testing chip are exposed to the atmosphere, condensation phenomenon is prone to occur. Therefore, to solve the problem of condensation phenomenon, in a technology known to the inventor, a large chamber full of dry gas is utilized, and all the low-temperature components of the testing apparatus are placed in the large chamber. However, the large chamber occupies a large space making the entire apparatus bulky, and the space within the chamber also limits the choice of various testing devices or accessories, such as testing boards. Moreover, to maintain the large chamber in a dry and low-temperature environment, energy consumption of the large chamber is also a serious problem.

### SUMMARY

In order to address the issue(s) mentioned above, the inventors provide an anti-condensation low-temperature testing module and a chip testing apparatus having the same. By performing conductive cooling and convection cooling of a low-temperature gas on a chip socket configured to accommodate a chip at the same time, the chip is immersed in a low-temperature environment, thereby ensuring that the chip is quickly cooled and maintained to have low-temperature. In addition, by continuously blowing low-temperature dry-gas, low-temperature testing modules and related components can have an anti-condensation function to prevent the condensation phenomenon of the testing apparatus which leads the chip or the testing apparatus to be damaged.

In some embodiments, an anti-condensation low-temperature testing module comprises a low-temperature dry-gas supplying device, a low-temperature chamber, a low-temperature generating device, and a communicating pipe. The low-temperature dry-gas supplying device is configured to provide a low-temperature dry-gas to a chip socket of a testing base. The low-temperature generating device is arranged in the low-temperature chamber and coupled to the testing base, and the low-temperature generating device is configured to cool down the testing base. One of two ends of the communicating pipe is in communication with the chip socket of the testing base, and the other end of the communicating pipe is in communication with the low-temperature chamber.

In some embodiments, the low-temperature chamber comprises a support base and a chamber enclosure. The low-temperature generating device is arranged on the support base, the chamber enclosure is arranged on the support base and surrounds the low-temperature generating device, and an exhaust channel is arranged between the support base and the chamber enclosure.

In some embodiments, the support base comprises a projecting frame, and the chamber enclosure and the projecting frame are stacked with each other and spaced apart from each other by a specific distance. The chamber enclosure comprises at least one raised portion, the at least one raised portion is configured to have another specific distance between the chamber enclosure and the support base, and the specific distance and the another specific distance together form the exhaust channel.

In some embodiments, the anti-condensation low-temperature testing module further comprises a testing-base enclosure and a testing-base plate. The testing-base enclosure surrounds at least one part of the testing base, and the testing-base plate is arranged on the testing base and the testing-base enclosure. The testing-base plate has a gas flow channel, one of two ends of the gas flow channel is in communication with the chip socket, and the other end of the gas flow channel is in communication with the low-temperature dry-gas supplying device.

In some embodiments, the anti-condensation low-temperature testing module further comprises a room-temperature dry-gas supplying device, and the room-temperature dry-gas supplying device is configured to provide a room-temperature dry-gas for the low-temperature chamber.

In some embodiments, the chip testing apparatus comprises a testing base, a low-temperature dry-gas supplying device, a low-temperature chamber, a low-temperature generating device, a communicating pipe, and a controller. The testing base comprises a chip socket, and the chip socket is configured to accommodate a testing chip. The low-temperature dry-gas supplying device is in communication with the chip socket of the testing base. The low-temperature generating device is arranged in the low-temperature chamber and coupled to the testing base. One of two ends of the communicating pipe is in communication with the chip socket of the testing base, and the other end of the communicating pipe is in communication with the low-temperature chamber. The controller is electrically connected to the testing base, the low-temperature dry-gas supplying device, and the low-temperature generating device, and the controller is configured to control the low-temperature generating device to cool down the testing base, configured to control the low-temperature dry-gas supplying device to provide a low-temperature dry-gas for the chip socket, and configured to control the testing base to test the testing chip.

In some embodiments, the chip testing apparatus further comprises a pressing head. The pressing head corresponds to the chip socket of the testing base and is electrically connected to the controller, and the controller is further configured to control the pressing head to move close to the chip socket to press against the testing chip or configured to control the pressing head to move away from the chip socket.

In conclusion, according to one or some embodiments, the convection cooling of the low-temperature dry-gas and the conductive cooling to the chip socket can be performed to create a low-temperature and dry environment for the testing chip at the same time, thereby ensuring the testing chip is maintained at a low-temperature without producing condensation phenomenon. In addition, the low-temperature chamber and the chip socket of the testing base are in communication with each other through the communicating pipe so that the low-temperature dry-gas in the chip socket can flow to the low-temperature chamber, that is, the low-temperature dry-gas can be recycled and reused. Herein, the related low-temperature assemblies in the low-temperature chamber can be maintained in a low-temperature and dry state, thereby reaching the anti-condensation effect of the chip testing apparatus.

### BRIEF DESCRIPTION OF DRAWINGS

The instant disclosure will become more fully understood from the detailed description given herein below for illustration only, and therefore not limitative of the instant disclosure, wherein:

FIG. 1 illustrates a perspective view of an implementation of a chip testing apparatus;

FIG. 2 illustrates a front view of the chip testing apparatus in FIG. 1;

FIG. 3 illustrates a schematic cross-sectional view of a first embodiment of the chip testing apparatus in FIG. 1;

FIG. 4 illustrates a module block diagram of the chip testing apparatus in FIG. 1;

FIG. 5 illustrates an enlarged partial view of the chip testing apparatus in FIG. 3;

FIG. 6 illustrates a schematic cross-sectional view of a low-temperature chamber in FIG. 1;

FIG. 7 illustrates a front plan view of a pressing head in FIG. 3; and

FIG. 8 illustrates a schematic cross-sectional view of a second embodiment of the chip testing apparatus in FIG. 1.

### DETAILED DESCRIPTION

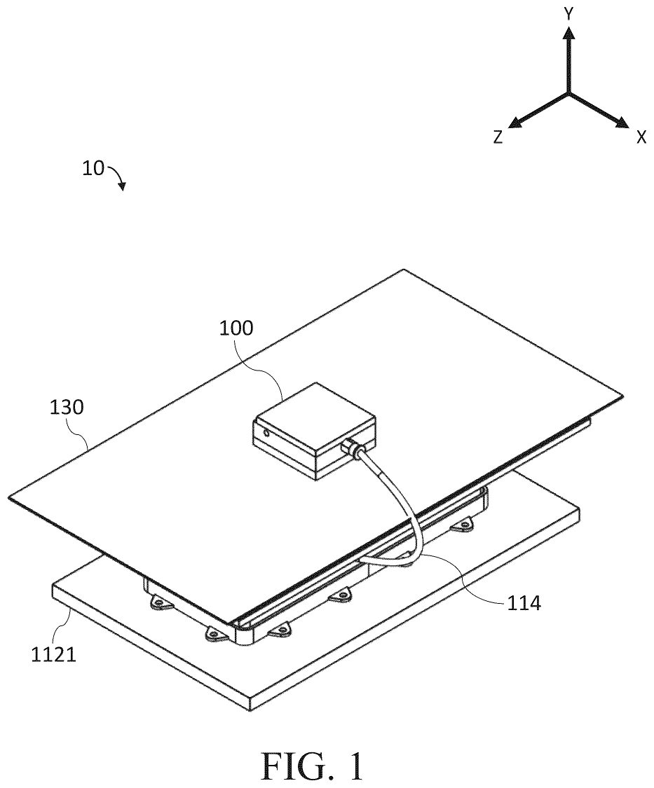

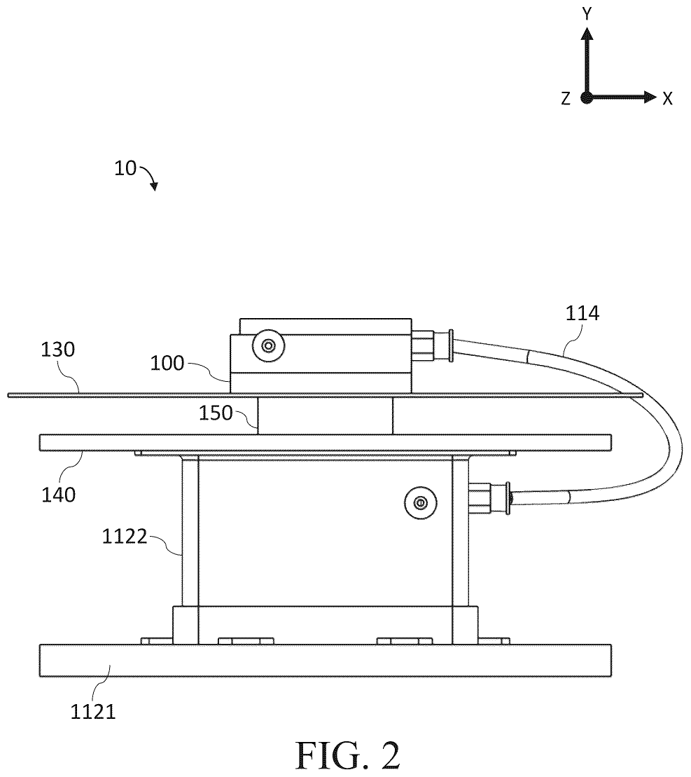

Please refer to FIG. 1 to FIG. 4. A chip testing apparatus 10 comprises a testing base 100, a low-temperature testing module 110, and a controller 120. The testing base 100 comprises a chip socket 101, and the chip socket 101 is configured to accommodate a testing chip 200. In some embodiments, the low-temperature testing module 110 comprises a low-temperature dry-gas supplying device 111, a low-temperature chamber 112, a low-temperature generating device 113, and a communicating pipe 114. The low-temperature generating device 113 is arranged in the low-temperature chamber 112. One of two ends of the communicating pipe 114 is in communication with the chip socket 101, and the other end of the communicating pipe 114 is in communication with the low-temperature chamber 112.

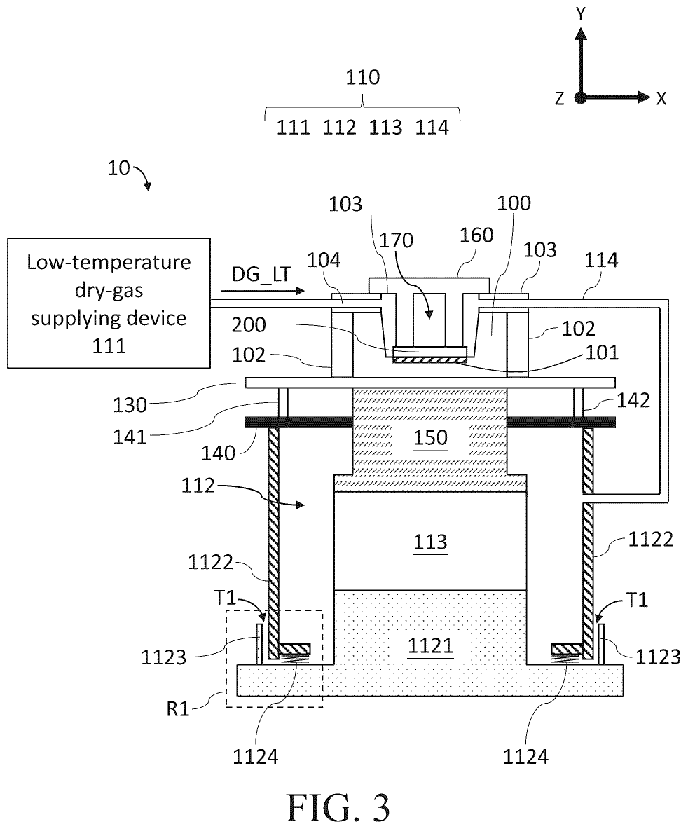

As shown in FIG. 3, in some embodiments, the anti-condensation low-temperature testing module 110 further comprises a testing-base enclosure 102 and a testing-base plate 103. The testing-base enclosure 102 surrounds at least one portion of the testing base 100. For example, the testing-base enclosure 102 surrounds the surrounding side walls of the testing base 100 to block the testing base 100 to prevent the testing base 100 from having the condensation phenomenon during low-temperature testing. In some embodiments, the testing-base enclosure 102 comprises a foam thermal preservation material, such as polystyrene (PS). The testing-base plate 103 is arranged on the testing base 100 and the testing-base enclosure 102. In some embodiments, the testing-base plate 103 has a gas flow channel 104, one of two ends of the gas flow channel 104 is in communication with the chip socket 101, and the other end of the gas flow channel 104 is in communication with the low-temperature dry-gas supplying device 111.

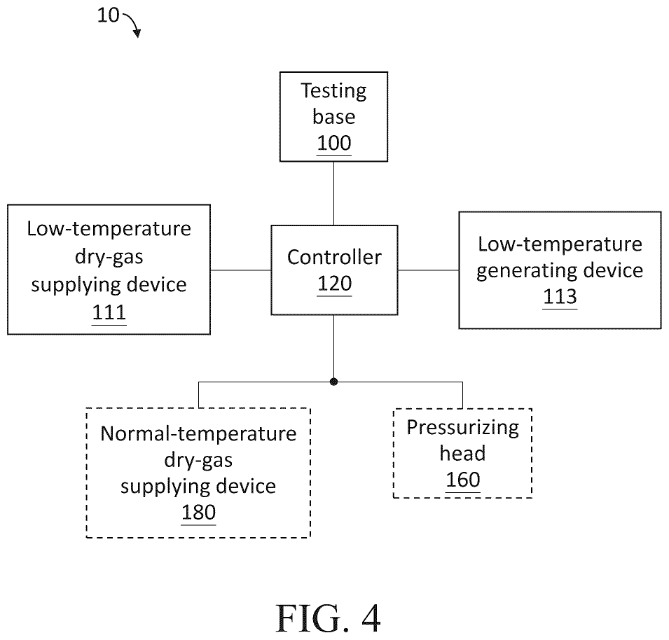

As shown in FIG. 3, in some embodiments, the chip testing apparatus 10 further comprises a testing circuit board 130, and the testing base 100 is arranged on the testing circuit board 130. In some embodiments, the testing circuit board 130 is dedicated for the testing chip 200; in other words, in some embodiments, in response to that the testing chip 200 is replaced, the testing circuit board 130 is replaced accordingly. Moreover, as shown in FIG. 4, the controller 120 is electrically connected to the testing base 100, the low-temperature dry-gas supplying device 111, and the low-temperature generating device 113.

As shown in FIG. 3, in some embodiments, the low-temperature chamber 112 comprises a support base 1121 and a chamber enclosure 1122. The low-temperature generating device 113 is arranged on the support base 1121, the chamber enclosure 1122 is arranged on the support base 1121 and surrounds the low-temperature generating device 113, and an exhaust channel T1 is arranged between the support base 1121 and the chamber enclosure 1122. In some embodiments, the chamber enclosure 1122 may comprise a housing and a foam thermal preservation material, in which the foam thermal preservation material surrounds the housing, and the foam thermal preservation material may be polystyrene (PS). In some embodiments, the foam thermal preservation material is configured to prevent the housing from contacting the atmosphere directly to prevent the occurrence of the condensation phenomenon.

As shown in FIG. 3, in some embodiments, the low-temperature chamber 112 further comprises a testing board fixture 140 and a thermal conductive pad 150. The testing board fixture 140 is arranged on the chamber enclosure 1122, and the thermal conductive pad 150 is arranged on the low-temperature generating device 113. The thermal conductive pad 150 passes through the testing board fixture 140 to contact the testing circuit board 130 directly, thereby making the low-temperature generating device 113 coupled to the testing base 100. The low-temperature generating device 113 cools the testing base 100 through the thermal conductive pad 150. In some embodiments, the thermal conductive pad 150 may be made of metal with a high thermal conductivity, such as copper.

In some embodiments, the testing board fixture 140 has a plurality of support pillars 141, 142. The plurality of support pillars 141, 142 is configured to support and fix the testing circuit board 130 to prevent the testing chip 200 from shaking due to an external force during testing.

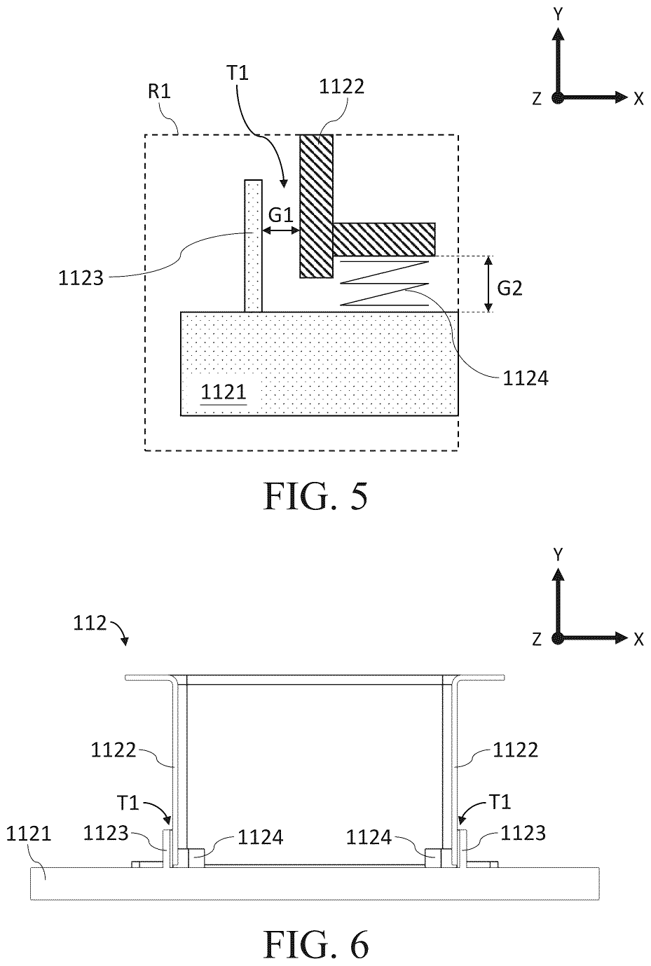

Please refer to FIG. 1 to FIG. 6. In some embodiments, the support base 1121 comprises a projecting frame 1123, which extends upward (Y direction). The chamber enclosure 1122 and the projecting frame 1123 are stacked with each other and spaced apart from each other by a specific distance G1 (as shown in FIG. 5, in which FIG. 5 corresponds to a dotted box R1 in FIG. 4). In some embodiments, the chamber enclosure 1122 comprises at least one raised portion 1124. The at least one raised portion 1124 is configured to have another specific distance G2 between the chamber enclosure 1122 and the support base 1121 (shown in FIG. 5), and the specific distances G1, G2 together form the exhaust tunnel T1. Take FIG. 6 for example, in some embodiments, the raised portions 1124 are arranged at four corners of a bottom portion of the chamber enclosure 1122 to raise the chamber enclosure 1122 to configure the specific distance G2 between the chamber enclosure 1122 and the support base 1121, thereby making the specific distances G1, G2 together form the exhaust tunnel T1.

As shown in FIG. 5, in some embodiments, the exhaust channel T1 formed by the specific distances G1, G2 is a labyrinth-seal structure, in which a labyrinth-seal path formed by the support base 1121, the chamber enclosure 1122, and the projecting frame 1123 makes the structure of the low-temperature chamber 112 more stable, and the labyrinth-seal path can effectively reduce the speed that gas flows out from the exhaust channel T1.

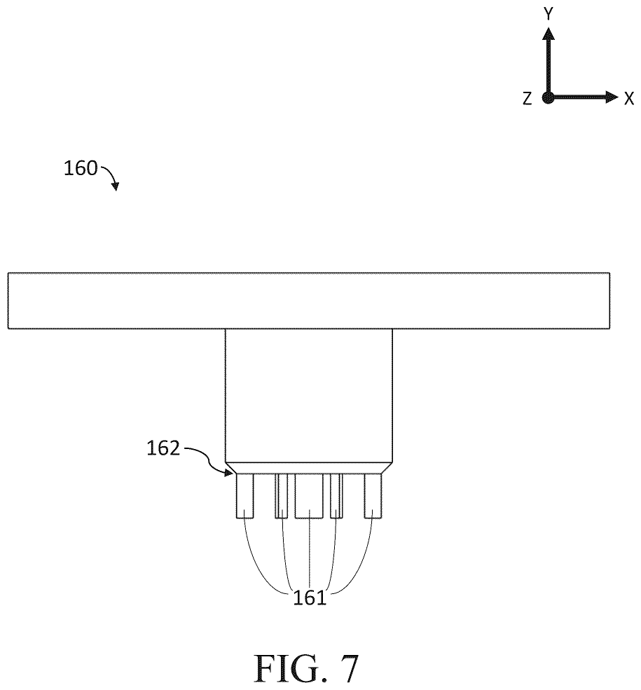

Please refer to FIG. 1 to FIG. 7. As shown in FIG. 7, in some embodiments, the chip testing apparatus 10 further comprises a pressing head 160. The pressing head 160 corresponds to the chip socket 101 of the testing base 100, and the pressing head 160 is electrically connected to the controller 120. In some embodiments, in response to that the chip testing apparatus 10 starts to operate, the controller 120 controls the pressing head 160 to move close to the chip socket 101 to press against the testing chip 200, and at the same time the controller 120 controls the low-temperature generating device 113 to perform conductive cooling to the testing base 100. In some embodiments, the low-temperature generating device 113 can be continuously operated for a long time to maintain the testing base 100 in a low-temperature state. In some embodiments, in response to that the pressing head 160 presses against the testing chip 200, the pressing head 160 and the chip socket 101 of the testing base 100 form another sealed low-temperature chamber 170. To easily distinguish the low-temperature chambers 112, 170 from each other, the low-temperature chamber 112 is referred to as a first chamber 112 and the low-temperature chamber 170 is referred to as a second chamber 170 hereinafter.

Then, the chip testing apparatus 10 generates a low-temperature dry-gas DG_LT through the low-temperature dry-gas supplying device 111 and provides the low-temperature dry-gas DG-LT for the chip socket 101 of the testing base 100. Specifically, in some embodiments, at this moment, the upper surface of the testing chip 200 contacts the low-temperature dry-gas DG_LT, and the surrounding side walls and the lower surface of the testing chip 200 contact the chip socket 101 of the testing base 100. Due to the convection mechanism of the low-temperature dry-gas DG-LT and the conduction mechanism of the testing base 100, the testing chip 200 can be completely immersed in a low-temperature environment so that the testing chip 200 can be quickly cooled down and continuously maintained to have the low-temperature.

After that, because the gas pressure in the second chamber 170 is greater than the gas pressure in the first chamber 112, the low-temperature dry-gas DG-LT flows to the first chamber 112 from the second chamber 170 through the communicating pipe 114. In addition, in response to that the gas pressure in the first chamber 112 is greater than the atmospheric pressure, the low-temperature dry-gas DG-LT flows out from the first chamber 112 through the exhaust channel T1. However, because the exhaust channel T1 of the present embodiment is the labyrinth-seal structure, the exhaust channel T1 can form a larger flow resistance to prevent the low-temperature dry-gas DG-LT from flowing out from the first chamber 112 quickly.

On the other hand, in response to that the testing chip 200 reaches to a specific temperature (for example, −40 degrees Celsius), the controller 120 controls the testing base 100 to start to test the testing chip 200. In response to that the testing process is completed, the chip testing apparatus 10 controls the pressing head 160 to move away from the chip socket 101 through the controller 120, and picks out the tested testing chip 200 and places another testing chip 200 through a pick-and-place device (not shown). However, in some other embodiments, the pick-and-place device can pick out the tested testing chip 200 and place another testing chip 200 after the chip testing apparatus 10 and the tested testing chip 200 recover to the room-temperature, thereby preventing from occurrence of the condensation phenomenon.

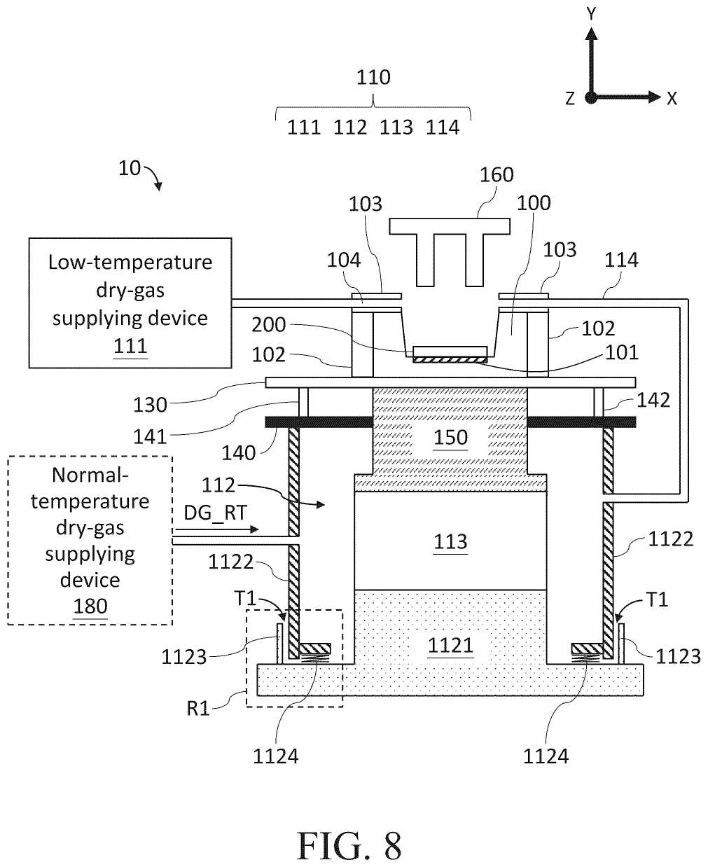

Please refer to FIG. 1 to FIG. 8. As shown in FIG. 8, in some embodiments, the chip testing apparatus 10 further comprises a room-temperature dry-gas supplying device 180, in which the room-temperature dry-gas supplying device 180 may be a gas bump with a gas drying system, such as a freeze dryer or an adsorption dryer. It is noted that, the present embodiment may be suitable for the chip testing apparatus 10 in a high-temperature and humid environment, because condensation phenomenon frequently occurs in the high-temperature and humid environment.

More specifically, in some embodiments, in response to that the testing process is completed, the controller 120 controls the low-temperature dry-gas supplying device 111 to stop operating, controls the room-temperature dry-gas supplying device 180 to generate a room-temperature dry-gas DG_RT, and provides the room-temperature dry-gas DG_RT for first chamber 112. Then, the room-temperature dry-gas DG_RT flows to the chip socket 101 from the first chamber 112 through the communicating pipe 114 to make the testing base 100 and the testing chip 200 recover to the room-temperature. After that, the room-temperature dry-gas DG_RT keeps the inside of the testing base 100 dry, thereby preventing the condensation phenomenon of the testing apparatus which leads the chip or the testing apparatus to be damaged. In other words, in some embodiments, the first chamber 112 and the second chamber 170 are further configured to be regarded as rewarming chambers and not limited to be regarded as the low-temperature chambers.

In some embodiments, the low-temperature dry-gas DG-LT may be a gas which maintains gaseous and dry at a low-temperature (for example, −20 degrees Celsius to −40 degrees Celsius), such as but not limited to nitrogen, oxygen, or argon. In some other embodiments, the low-temperature dry-gas supplying device 111 may be a high-pressure cylinder or a low-temperature gas generating apparatus known to the industry. In addition, low-temperature dry-gas supplying device 111 may also be equipped with the gas drying system, such as a freeze dryer or an adsorption dryer. In some embodiments, the room-temperature dry-gas DG-RT may be a gas which maintains gaseous and dry at a room-temperature (for example, 20 degrees Celsius to 30 degrees Celsius), such as but not limited to inert gas (such as argon), nitrogen, or oxygen.

In some embodiments, the chip testing apparatus 10 can control the flow of the low-temperature dry-gas DG-LT generated by the low-temperature dry-gas supplying device 111 through the controller 120. Please refer to TABLE 1, TABLE 1 shows temperatures of the testing chip 200 tested under different flows of room-temperature dry-gases DG_RT. As shown in Table 1, in some embodiments, the greater the flow of the room-temperature dry-gases DG_RT, the slower the low-temperature dry-gas DG-LT flows out from the first chamber 112 (in other words, in some embodiments, the slower the newly-generated low-temperature dry-gas DG-LT flows to the second chamber 170). At this moment, the temperature of the testing chip 200 is higher, and the humidity of the first chamber 112 and the humidity of the second chamber 170 are lower. In some other embodiments, the less the flow of the room-temperature dry-gases DG_RT, the faster the low-temperature dry-gas DG-LT flows out from the first chamber 112 (in other words, in some embodiments, the faster the newly-generated low-temperature dry-gas DG-LT flows to the second chamber 170). At this moment, the temperature of the testing chip 200 is lower, and the humidity of the first chamber 112 and the humidity of the second chamber 170 are higher. Therefore, according to different ambient temperatures or humidity, the chip testing apparatus 10 can adjust the flow of the room-temperature dry-gases DG_RT to an appropriate value so that a balance can be reached between the cooling function and the anti-condensation function.

TABLE 1

| Flow (LPM) | 0 | 10 | 30 | 50 |
|---|---|---|---|---|
| Temperature of | −30.58 | −30.61 | −30.7 | −30.76 |
| the testing chip 200 | | | | |
| (Celsius temperature) | | | | |
| Outlet surface temperature of | 20.05 | 21.26 | 23.22 | 23.26 |
| the second chamber 170 | | | | |
| (Celsius temperature) | | | | |

In some embodiments, the low-temperature generating device 113 may be a hardware element which has the cooling function, such as but not limited to an evaporator, a semiconductor cooler, a thermoelectric cooling chip, or other cooling device.

In some embodiments, the controller 120 may be a hardware element which has a control function, such as but not limited to a central processing unit (CPU), a microprocessor, a digital signal processor (DSP), a complex programmable logic device (CPLD), a field programmable gate array (FPGA), an application specific integrated circuit (ASIC), or a microcontroller unit (MCU). In addition, the controller 120 may be any single or multiple processor computing devices/systems that execute computer readable instructions, such as but not limited to a workstation, a laptop computer, a client terminal, a server, a distributed computing system, a handheld device, or any other computing systems/devices. Under a basic configuration, the controller 120 may include at least one processor and system memory.

In some embodiments, the testing circuit board 130 may be a hardware element having the chip socket 101, and the testing circuit board 130 may be, such as but not limited, to a printed circuit board (PCB), motherboard, or an evaluation board.

As shown in FIG. 7, in some embodiments, the pressing head 160 comprises a plurality of pressing pillars 161, and the plurality of pressing pillars 161 is evenly arranged on the lower surface 162 of the pressing head 160 so that the pressing head 160 can evenly press against the testing chip 200, thereby ensuring that all pins on the testing chip 200 are electrically connected to the pin slots on the chip socket 101 of the testing base 100, respectively. In addition, because is an appropriate spacing distance is between adjacent two of the plurality of pressing pillars 161, it is ensured that the low-temperature dry-gas DG_LT can flow through the chip socket 101 to contact the testing chip 200.

In some embodiments, the testing chip 200 may be various types of packaged chips, such as but not limited to a PoP chip, a ball grid array (BGA) chip, a chip scale package (CSP) chip, a plastic leaded chip carrier (PLCC) chip, a plastic dual in-line package (PDIP) chip, a chip-on-board (COB) chip, a ceramic dual in-line package (CERDIP) chip, a molded quad flat package (MQFP) chip, a thin quad flat package (TQFP) chip, a system-on-integrated circuit (SOIC) chip, a shrink small outline package (SSOP) chip, a thin small outline package (TSOP) chip, a system-in-package (SIP) chip, a multi-chip package (MCP) chip, a wafer fabrication package (WFP) chip, a wafer stacked package (WSP) chip, or a silicon photonics chip.

In conclusion, according to one or some embodiments, the low-temperature testing module 110 and the chip testing apparatus 10 can perform conductive cooling and convection cooling to the testing chip 200 at the same time. Herein, the testing chip 200 is immersed in a low-temperature and dry environment so that the testing chip can quickly cool down and maintain at a predetermined temperature easily and stably. In addition, according to one or some embodiments, since the surface of the chip or the surface of the apparatus will not produce condensation phenomenon during or after the testing process, the chip or the testing apparatus can be prevented from being damaged. Therefore, the efficiency and safety during the testing process can be effectively improved.

Although the present disclosure has been described in considerable detail with reference to certain preferred embodiments thereof, the disclosure is not for limiting the scope of the invention. Persons having ordinary skill in the art may make various modifications and changes without departing from the scope and spirit of the disclosure. Therefore, the scope of the appended claims should not be limited to the description of the preferred embodiments described above.

What is claimed is:

1. An anti-condensation low-temperature testing module comprising:
a low-temperature dry-gas supplying device configured to provide a low-temperature dry-gas to a chip socket of a testing base;
a low-temperature chamber;
a low-temperature generating device arranged in the low-temperature chamber and coupled to the testing base, wherein the low-temperature generating device is configured to cool down the testing base; and
a communicating pipe, wherein one of two ends of the communicating pipe is in communication with the chip socket of the testing base, and the other end of the communicating pipe is in communication with the low-temperature chamber.

2. The anti-condensation low-temperature testing module according to claim 1, wherein the low-temperature chamber comprises a support base and a chamber enclosure;
the low-temperature generating device is arranged on the support base, the chamber enclosure is arranged on the support base and surrounds the low-temperature generating device, and an exhaust channel is arranged between the support base and the chamber enclosure.

3. The anti-condensation low-temperature testing module according to claim 2, wherein the support base comprises a projecting frame, and the chamber enclosure and the projecting frame are stacked with each other and spaced apart from each other by a specific distance;
the chamber enclosure comprises at least one raised portion, the at least one raised portion is configured to have another specific distance between the chamber enclosure and the support base, and the specific distance and the another specific distance together form the exhaust channel.

4. The anti-condensation low-temperature testing module according to claim 1 further comprising a testing-base enclosure and a testing-base plate, wherein the testing-base enclosure surrounds at least one part of the testing base, and the testing-base plate is arranged on the testing base and the testing-base enclosure;
wherein the testing-base plate has a gas flow channel, one of two ends of the gas flow channel is in communication with the chip socket, and the other end of the gas flow channel is in communication with the low-temperature dry-gas supplying device.

5. The anti-condensation low-temperature testing module according to claim 1 further comprising a room-temperature dry-gas supplying device, wherein the room-temperature dry-gas supplying device is configured to provide a room-temperature dry-gas for the low-temperature chamber.

6. A chip testing apparatus comprising:
a testing base comprising a chip socket, wherein the chip socket is configured to accommodate a testing chip;
a low-temperature dry-gas supplying device in communication with the chip socket of the testing base;
a low-temperature chamber;
a low-temperature generating device arranged in the low-temperature chamber and coupled to the testing base;
a communicating pipe, wherein one of two ends of the communicating pipe is in communication with the chip socket of the testing base, and the other end of the communicating pipe is in communication with the low-temperature chamber; and
a controller electrically connected to the testing base, the low-temperature dry-gas supplying device, and the low-temperature generating device, wherein the controller is configured to control the low-temperature generating device to cool down the testing base, configured to control the low-temperature dry-gas supplying device to provide a low-temperature dry-gas for the chip socket, and configured to control the testing base to test the testing chip.

7. The chip testing apparatus according to claim 6 further comprising a testing-base enclosure and a testing-base plate, wherein the testing-base enclosure surrounds at least one part of the testing base, and the testing-base plate is arranged on the testing base and the testing-base enclosure;
wherein the testing-base plate has a gas flow channel, one of two ends of the gas flow channel is in communication with the chip socket, and the other end of the gas flow channel is in communication with the low-temperature dry-gas supplying device.

8. The chip testing apparatus according to claim 6, wherein the low-temperature chamber comprises a support base and a chamber enclosure;
the low-temperature generating device is arranged on the support base, and the chamber enclosure is arranged on the support base and surrounds the low-temperature generating device;
the support base comprises a projecting frame, and the chamber enclosure and the projecting frame are stacked with each other and spaced apart from each other by a specific distance;
the chamber enclosure comprises at least one raised portion, the at least one raised portion is configured to have another specific distance between the chamber enclosure and the support base, and the specific distance and the another specific distance together form an exhaust tunnel.

9. The chip testing apparatus according to claim 6 further comprising a room-temperature dry-gas supplying device, wherein the room-temperature dry-gas supplying device, and the controller is further configured to control the room-temperature dry-gas supplying device to provide a room-temperature dry-gas for the low-temperature chamber.

10. The chip testing apparatus according to claim 6 further comprising a pressing head, wherein the pressing head corresponds to the chip socket of the testing base and is electrically connected to the controller, and the controller is further configured to control the pressing head to move close to the chip socket to press against the testing chip or configured to control the pressing head to move away from the chip socket.
